(19) United States
(12) Patent Application Publication
(10) Pub. No.: US 2025/0125797 A1
(43) Pub. Date: Apr. 17, 2025

(54) HIGH-FREQUENCY SWITCH CIRCUIT

(71) Applicant: NEC Corporation, Tokyo (JP)

(72) Inventor: Koki TANJI, Tokyo (JP)

(73) Assignee: NEC Corporation, Tokyo (JP)

(21) Appl. No.: 18/898,850

(22) Filed: Sep. 27, 2024

(30) Foreign Application Priority Data
Oct. 12, 2023 (JP) 2023-176547

(51) Int. Cl. H03K 17/06

(52) U.S. Cl. CPC H03K 17/06

(57) ABSTRACT

A high-frequency switch circuit according to the present disclosure includes: an input terminal; an output terminal; a first switch connected between the input terminal and the output terminal; a first transmission line, one end of the first transmission line being connected to the input terminal and an input-side terminal of the first switch; a second transmission line, one end of the second transmission line being connected to the output terminal and an output-side terminal of the first switch; and a second switch connected between another end of the first transmission line and another end of the second transmission line, the second switch being controlled so that a conduction state and a cut-off state are exclusive to the first switch.

### INCORPORATION BY REFERENCE

This application is based upon and claims the benefit of priority from Japanese patent application No. 2023-176547, filed on Oct. 12, 2023, the disclosure of which is incorporated herein in its entirety by reference.

### TECHNICAL FIELD

The present disclosure relates to a high-frequency switch circuit.

### BACKGROUND ART

The high-frequency switch circuit disclosed in Japanese Unexamined Patent Application Publication No. 2016-10045 includes a first transmission line, a first transistor, a second transistor, and a second transmission line. One end of the first transmission line is connected to a first terminal, and when a first high-frequency signal to be transmitted is input, the line length becomes an integral multiple of ¼ of a wavelength of the first high-frequency signal. One end of the first transistor is connected to the other end of the first transmission line, the other end thereof is connected to the second terminal, and a first control signal is input to a control terminal thereof. One end of the second transistor is connected to the second terminal, and a second control signal is input to a control terminal thereof. One end of the second transmission line is connected to the other end of the second transistor, and the other end thereof is connected to the third terminal, and when a second high-frequency signal to be transmitted is input, the line length becomes an integral multiple of ¼ of a wavelength of the second high-frequency signal.

### SUMMARY

However, regarding the high-frequency switch circuit disclosed in Japanese Unexamined Patent Application Publication No. 2016-10045, in recent years it has been observed that a problem occurs; namely, the frequency of a signal handled by an electric circuit tends to increase, and hence a sufficient isolation cannot be obtained.

The present disclosure has been made to solve the above-described problem and an object thereof is to improve isolation characteristics of a high-frequency switch in a cut-off state.

A high-frequency switch circuit according to the present disclosure includes: an input terminal; an output terminal; a first switch connected between the input terminal and the output terminal; a first transmission line, one end of the first transmission line being connected to the input terminal and an input-side terminal of the first switch; a second transmission line, one end of the second transmission line being connected to the output terminal and an output-side terminal of the first switch; and a second switch connected between another end of the first transmission line and another end of the second transmission line, the second switch being controlled so that a conduction state and a cut-off state are exclusive to the first switch.

### BRIEF DESCRIPTION OF DRAWINGS

The above and other aspects, features and advantages of the present disclosure will become more apparent from the following description of certain example embodiments when taken in conjunction with the accompanying drawings, in which:

FIG. 1 is a diagram for explaining a configuration and an operation of a high-frequency switch circuit according to the present disclosure;

FIG. 2 is an equivalent circuit diagram of the high-frequency switch circuit according to the present disclosure;

FIG. 3 is a diagram for explaining a configuration and an operation of a high-frequency switch circuit according to a comparative example;

FIG. 4 is an equivalent circuit diagram of the high-frequency switch circuit according to the comparative example;

FIG. 5 is a graph illustrating operation characteristics of the high-frequency switch circuit according to the present disclosure;

FIG. 6 is a graph illustrating operation characteristics of the high-frequency switch circuit according to the comparative example; and

FIG. 7 is a diagram for explaining an example of a specific circuit of the high-frequency switch circuit according to the present disclosure.

### EXAMPLE EMBODIMENT

Example embodiments will be described hereinafter with reference to the drawings. For the clarification of the description, the following descriptions and the drawings are partially omitted and simplified as appropriate. Further, the same elements are denoted by the same reference numerals or symbols throughout the drawings, and redundant descriptions are omitted as necessary. Further, although descriptions will be given with reference to the drawings, the drawings used to illustrate a certain example embodiment are not applicable only to the certain example embodiment. Each of the drawings may be applied to all of the example embodiments.

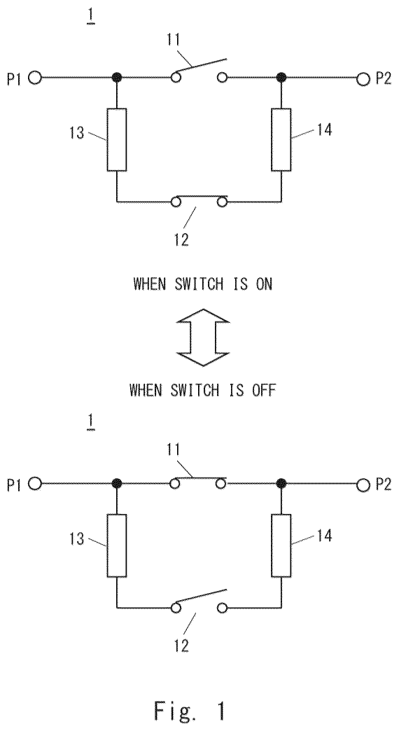

FIG. 1 is a diagram for explaining a configuration and an operation of a high-frequency switch circuit 1 according to the present disclosure. As shown in FIG. 1, the high-frequency switch circuit 1 according to the present disclosure includes a first switch (e.g., a switch 11), a second switch (e.g., a switch 12), a first transmission line (e.g., a microstrip line 13), a second transmission line (e.g., a microstrip line 14), an input terminal P1, and an output terminal P2. Note that, although the input terminal P1 and the output terminal P2 are named as input-side and output-side terminals as an example, the input terminal may be on the output side and the output terminal may be on the input side.

A microstrip line, a strip line, a coplanar line, a coaxial line, or the like may be used as both the first transmission line and the second transmission line, and a description will be given below of an example of a case in which a microstrip line is used for them.

The switch 11 is connected between the input terminal P1 and the output terminal P2. One end of the microstrip line 13 is connected to the input terminal P1 and the input-side terminal of the switch 11. One end of the microstrip line 14 is connected to the output terminal P2 and the output-side terminal of the switch 11. The switch 12 is a switch controlled so that a conduction state and a cut-off state are exclusive to the first switch. Further, the switch 12 is connected between the other end of the microstrip line 13 and the other end of the microstrip line 14.

Further, a description will be given below of an example of a case in which Field Effect Transistor (FET) transistors are used as the switches 11 and 12. However, a PIN diode, a Microelectromechanical System (MEMS), a GaAs pHEMT, a bulk CMOS, a Silicon on Insulator (SOI), a Silicon on Sapphire (SOS), or the like may be used for the switches 11 and 12. Note that elements that can be used as the switches 11 and 12 may be any elements that can be used as these switches at a high frequency (a microwave, a millimeter wave), and are not limited to particular elements.

Note that, in the high-frequency switch circuit 1, the switch 11 is controlled so that it is in a cut-off state when the high-frequency switch circuit 1 is in a switch-on state (“when the switch is ON” in FIG. 1; the same applies to the following description) in which a signal is transmitted from the input terminal P1 to the output terminal P2, while the switch 11 is controlled so that it is in a conduction state when the high-frequency switch circuit 1 is in a switch-off state (“when the switch is OFF” in FIG. 1; the same applies to the following description) in which an output of a signal from the output terminal P2 is stopped. On the other hand, the switch 12 is controlled so that it is in a conduction state when the high-frequency switch circuit 1 is in the switch-on state, while the switch 12 is controlled so that it is in a cut-off state when the high-frequency switch circuit 1 is in the switch-off state.

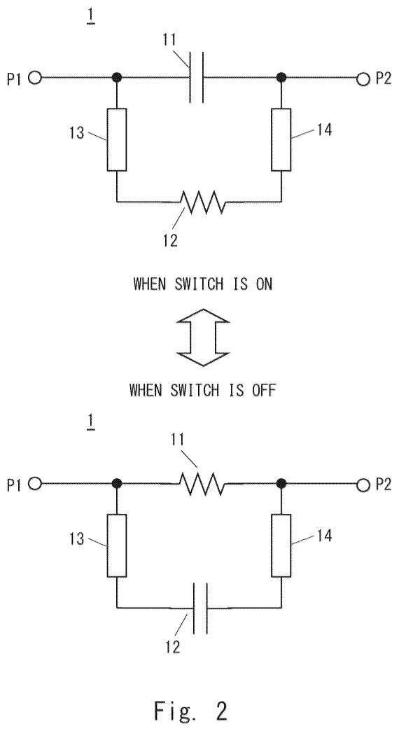

An equivalent circuit diagram of the high-frequency switch circuit 1 according to the disclosure is shown in FIG. 2. In FIG. 2, what electrical characteristics the switches 11 and 12 exhibit with respect to a high-frequency signal is equivalently shown using electric elements. In the switches 11 and 12, a resistance component becomes dominant with respect to a high-frequency signal in a conduction state, and a capacitor component becomes dominant with respect to a high-frequency signal in a cut-off state. Therefore, in FIG. 2, a resistance is shown as an equivalent circuit of the switch in a conduction state, and a capacitor is shown as an equivalent circuit of the switch in a cut-off state.

Further, in the high-frequency switch circuit 1 according to the present disclosure, each of the microstrip lines 13 and 14 is formed so as to have a length of ¼ of a wavelength of a used frequency, or a length obtained by adding a length of ¼ of a wavelength of a used frequency to a length of an integral multiple of ½ of a wavelength of the used frequency. An isolation characteristic between the input terminal and the output terminal when the switch 11 is in a conduction state and the switch 12 is in a cut-off state (i.e., when the switch is off) is maximized at frequencies corresponding to the respective lengths of the microstrip lines 13 and 14. Note that although the characteristic impedance (Z0) of the transmission line is basically 50Ω, it can be changed in accordance with the connection circuits before and after the transmission line in order to optimize the insertion loss. Further, the length of the microstrip line may be an electric length.

In the high-frequency switch circuit 1 according to the present disclosure, when the switch circuit is switched on, a signal is transmitted from the input terminal P1 to the output terminal P2 through the microstrip line 13, the switch 12, and the microstrip line 14 in this order. Meanwhile, in the high-frequency switch circuit 1 according to the present disclosure, when the switch circuit is switched off, the switch 12 functions as a capacitor, so that the microstrip lines 13 and 14 function as open stubs to increase the isolation between the input terminal P1 and the output terminal P2.

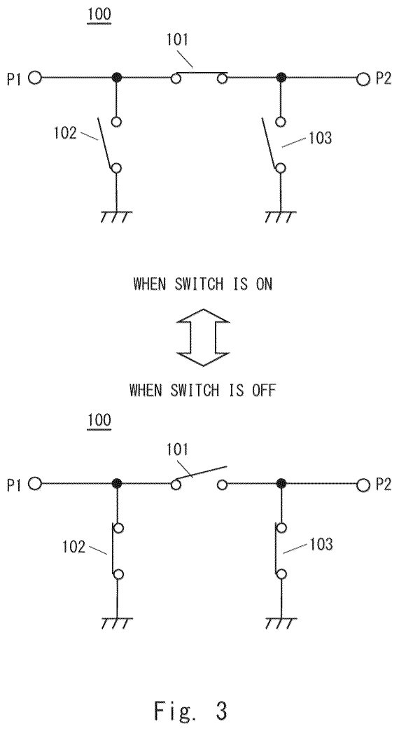

In order to explain the characteristics of the high-frequency switch circuit 1 according to the present disclosure, a high-frequency switch circuit similar to the high-frequency switch circuit disclosed in Japanese Unexamined Patent Application Publication No. 2016-10045 as a comparative example will be described as a high-frequency switch circuit 100 according to the comparative example. FIG. 3 is a diagram for explaining a configuration and an operation of the high-frequency switch circuit according to the comparative example.

As shown in FIG. 3, the high-frequency switch circuit 100 according to the comparative example includes three switches, i.e., switches 101 to 103. The switch 101 is connected between the input terminal P1 and the output terminal P2. One end of the switch 102 is connected between the input terminal P1 and the input-side terminal of the switch 101, and the other end thereof is connected to the ground terminal. One end of the switch 103 is connected between the output terminal P2 and the output-side terminal of the switch 101, and the other end thereof is connected to the ground terminal.

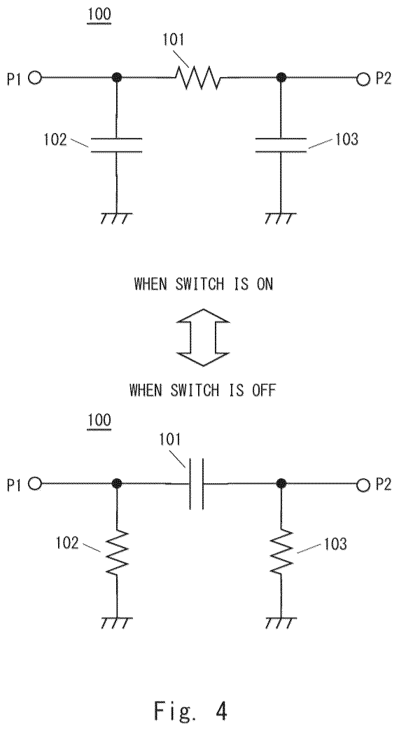

FIG. 4 is an equivalent circuit diagram of the high-frequency switch circuit 100 according to the comparative example. In FIG. 4, like in the case shown in FIG. 2, a resistance is an equivalent circuit of the switch in a conduction state, and a capacitor is an equivalent circuit of the switch in a cut-off state. As shown in FIG. 4, in the high-frequency switch circuit 100 according to the comparative example, isolation is increased by making the switches 102 and 103 function as shunts in a switch-off state. However, in the high-frequency switch circuit 100 according to the comparative example, since the switches 102 and 103 function as capacitors when the switch is on, the insertion loss increases. On the other hand, as shown in FIG. 2, the high-frequency switch circuit 1 according to the present disclosure has a feature that there is only one capacitor on the line both when the switch is on and off and the capacitors are not arranged in the ground, and thus the insertion loss is small.

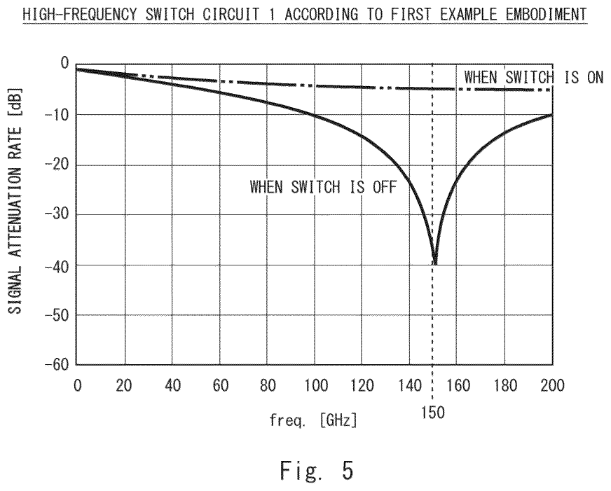

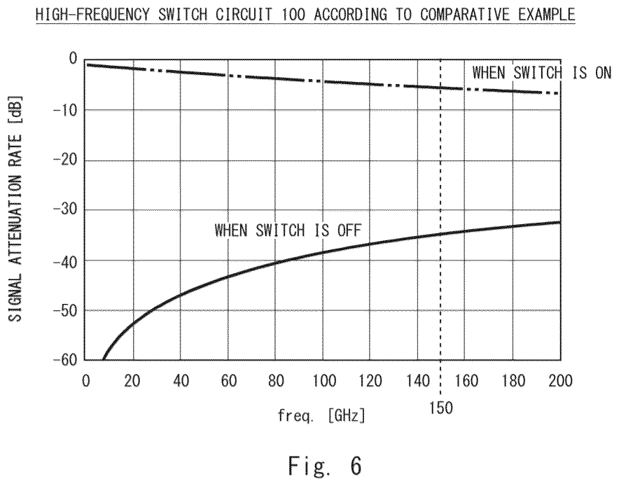

Next, the characteristics of the high-frequency switch circuit 1 according to the present disclosure will be described with reference to FIGS. 5 and 6. FIG. 5 is a graph illustrating operation characteristics of the high-frequency switch circuit according to the present disclosure, while FIG. 6 is a graph illustrating operation characteristics of the high-frequency switch circuit according to the comparative example. Note that FIGS. 5 and 6 show the frequency characteristics when a signal in which the frequency is set at 150 GHz is supplied to the high-frequency switch circuit 1 and the high-frequency switch circuit 100, respectively. In the high-frequency switch circuit, the insertion loss and the isolation characteristics in the signal band of the used frequency are important characteristics.

When FIG. 5 is compared to FIG. 6, it can be seen that, in the high-frequency switch circuit 1 according to the present disclosure, the loss when the switch is on is slightly improved as compared to that in the case of the high-frequency switch circuit 100 according to the comparative example (the value when the switch is ON at around 150 GHz in FIGS. 5 and 6). Further, when FIG. 5 is compared to FIG. 6, it can be seen that, in the high-frequency switch circuit 1 according to the present disclosure, the isolation characteristic when the switch is off is improved by about 6 dB as compared to that in the case of the high-frequency switch circuit 100 according to the comparative example (the value when the switch is OFF at around 150 GHz in FIGS. 5 and 6).

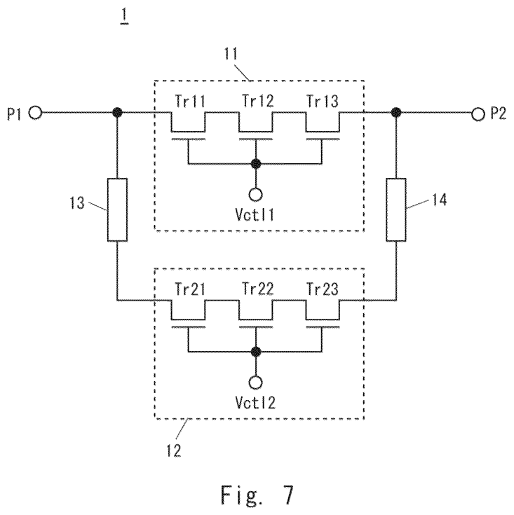

An example of a specific circuit of the high-frequency switch circuit 1 according to the present disclosure will be described below. FIG. 7 is a diagram for explaining the example of a specific circuit of the high-frequency switch circuit according to the present disclosure. As shown in FIG. 7, the switches 11 and 12 connect, for example, three FET transistors (transistors Tr11 to Tr13 and transistors Tr21 to Tr23 shown in FIG. 7) in series, and supply the same control signals to the three transistors connected in series. In the example shown in FIG. 7, a control signal Vctl1 is supplied to the transistors Tr11 to Tr13, and a control signal Vctl2 is supplied to the transistors Tr21 to Tr23. The control signals Vctl1 and Vctl2 bring the switches 11 and 12 into a conduction state when the level of voltage of the control signals Vctl1 and Vctl2 becomes high (e.g., a power supply voltage), while the control signals Vctl1 and Vctl2 bring the switches 11 and 12 into a cut-off state when the level of voltage of the control signals Vctl1 and Vctl2 becomes low (e.g., a ground voltage).

As described above, in the high-frequency switch circuit 1 according to the present disclosure, by providing transmission lines that serve as stubs before and after the switch 11 and connecting the other ends of the transmission lines to the switch 12, it is possible to both reduce the insertion loss and achieve high isolation characteristics.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment can be appropriately combined with at least one of example embodiments.

Each of the drawings or figures is merely an example to illustrate one or more example embodiments. Each figure may not be associated with only one particular example embodiment, but may be associated with one or more other example embodiments. As those of ordinary skill in the art will understand, various features or steps described with reference to any one of the figures can be combined with features or steps illustrated in one or more other figures, for example, to produce example embodiments that are not explicitly illustrated or described. Not all of the features or steps illustrated in any one of the figures to describe an example embodiment are necessarily essential, and some features or steps may be omitted. The order of the steps described in any of the figures may be changed as appropriate.

The whole or part of the example embodiments disclosed above can be described as, but not limited to, the following supplementary notes.

### Supplementary Note 1

A high-frequency switch circuit comprising:
an input terminal;
an output terminal;
a first switch connected between the input terminal and the output terminal;
a first transmission line, one end of the first transmission line being connected to the input terminal and an input-side terminal of the first switch;
a second transmission line, one end of the second transmission line being connected to the output terminal and an output-side terminal of the first switch; and
a second switch connected between another end of the first transmission line and another end of the second transmission line, the second switch being controlled so that a conduction state and a cut-off state are exclusive to the first switch.

### Supplementary Note 2

The high-frequency switch circuit according to supplementary note 1, wherein each of the first transmission line and the second transmission line is formed so as to have a length of ¼ of a wavelength of a used frequency, or a length obtained by adding a length of ¼ of a wavelength of a used frequency to a length of an integral multiple of ½ of a wavelength of the used frequency.

### Supplementary Note 3

The high-frequency switch circuit according to supplementary note 1 or 2, wherein an isolation characteristic between the input terminal and the output terminal when the first switch is in a conduction state and the second switch is in a cut-off state is maximized at frequencies corresponding to the respective lengths of the first and the second transmission lines.

### Supplementary Note 4

The high-frequency switch circuit according to any one of supplementary notes 1 to 3, wherein each of the first switch and the second switch is formed of one of a Field Effect Transistor (FET) transistor, a PIN diode, a Microelectromechanical System (MEMS), a GaAs pHEMT, a bulk CMOS, a Silicon on Insulator (SOI), and a Silicon on Sapphire (SOS).

### Supplementary Note 5

The high-frequency switch circuit according to any one of supplementary notes 1 to 4, wherein
the first switch is controlled so that it is in a cut-off state when the high-frequency switch circuit is in a switch-on state in which a signal is transmitted from the input terminal to the output terminal, while the first switch is controlled so that it is in a conduction state when the high-frequency switch circuit is in a switch-off state in which an output of a signal from the output terminal is stopped, and
the second switch is controlled so that it is in a conduction state when the high-frequency switch circuit is in the switch-on state, while the second switch is controlled so that it is in a cut-off state when the high-frequency switch circuit is in the switch-off state.

According to the present disclosure, it is possible to improve isolation characteristics of a high-frequency switch in a cut-off state.

What is claimed is:

1. A high-frequency switch circuit comprising:
an input terminal;
an output terminal;
a first switch connected between the input terminal and the output terminal;
a first transmission line, one end of the first transmission line being connected to the input terminal and an input-side terminal of the first switch;
a second transmission line, one end of the second transmission line being connected to the output terminal and an output-side terminal of the first switch; and
a second switch connected between another end of the first transmission line and another end of the second transmission line, the second switch being controlled so that a conduction state and a cut-off state are exclusive to the first switch.

2. The high-frequency switch circuit according to claim 1, wherein each of the first transmission line and the second transmission line is formed so as to have a length of ¼ of a wavelength of a used frequency, or a length obtained by adding a length of ¼ of a wavelength of a used frequency to a length of an integral multiple of ½ of a wavelength of the used frequency.

3. The high-frequency switch circuit according to claim 2, wherein an isolation characteristic between the input terminal and the output terminal when the first switch is in a conduction state and the second switch is in a cut-off state is maximized at frequencies corresponding to the respective lengths of the first and the second transmission lines.

4. The high-frequency switch circuit according to claim 1, wherein each of the first switch and the second switch is formed of one of a Field Effect Transistor (FET) transistor, a PIN diode, a Microelectromechanical System (MEMS), a GaAs pHEMT, a bulk CMOS, a Silicon on Insulator (SOI), and a Silicon on Sapphire (SOS).

5. The high-frequency switch circuit according to claim 1, wherein
the first switch is controlled so that it is in a cut-off state when the high-frequency switch circuit is in a switch-on state in which a signal is transmitted from the input terminal to the output terminal, while the first switch is controlled so that it is in a conduction state when the high-frequency switch circuit is in a switch-off state in which an output of a signal from the output terminal is stopped, and
the second switch is controlled so that it is in a conduction state when the high-frequency switch circuit is in the switch-on state, while the second switch is controlled so that it is in a cut-off state when the high-frequency switch circuit is in the switch-off state.
